(19) United States
(12) Patent Application Publication
(10) Pub. No.: US 2014/0346037 A1
(43) Pub. Date: Nov. 27, 2014

(54) SPUTTER DEVICE

(71) Applicant: TOKYO ELECTRON LIMITED, Tokyo (JP)

(72) Inventors: Shigeru MIZUNO, Tokyo (JP); Atsushi GOMI, Nirasaki City (JP); Tetsuya MIYASHITA, Nirasaki City (JP); Tatsuo HATANO, Nirasaki City (JP); Yasushi MIZUSAWA, Nirasaki City (JP)

(21) Appl. No.: 14/453,754

(22) Filed: Aug. 7, 2014

Related U.S. Application Data
(63) Continuation of application No. PCT/JP2013/000728, filed on Feb. 12, 2013.

(30) Foreign Application Priority Data
Feb. 13, 2012 (JP) 2012-028715

(51) Int. Cl. H01J 37/34

(52) U.S. Cl. CPC H01J 37/3411; H01J 37/345; H01J 2237/332
USPC 204/298.08

(57) ABSTRACT

There is provided a sputter device in which a conductive target having a planar and circular shape is disposed so as to face a workpiece substrate mounted on a mounting part located within a vacuum chamber, includes: a direct current power supply configured to apply a negative direct current voltage to the target; an opposing electrode installed at the opposite side of the workpiece substrate from the target so as to face the target; and a target high-frequency power supply connected to the target and configured to supply high-frequency power to the target in order to generate a high-frequency electric field between the opposing electrode and the target, wherein the distance between the target and the workpiece substrate during a sputtering process being 30 mm or less.

### CROSS-REFERENCE TO RELATED APPLICATIONS

This application is a Continuation application of PCT International Application No. PCT/JP2013/000728, filed on Feb. 12, 2013, which claimed the benefit of Japanese Patent Application No. 2012-028715, filed on Feb. 13, 2012, in the Japan Patent Office, the entire content of each of which is hereby incorporated by reference.

### TECHNICAL FIELD

The present disclosure relates to a sputter device that performs film deposition with respect to a substrate by sputtering a target.

### BACKGROUND

A magnetron sputter device used in a semiconductor device manufacturing process has, e.g., a configuration in which a target made of a film deposition material is disposed to be located opposite to a substrate within a vacuum chamber kept in a low-pressure atmosphere and in which a magnet member is installed at the side of an upper surface of the target. In case where the target is a conductive material, e.g., a metal, a magnetic field is formed near a lower surface of the target with a negative direct current voltage applied to the target. An adhesion-preventing shield (not shown) is installed in order to prevent particles from adhering to an inner wall of the vacuum chamber.

FIG. 10 is a plan view of a magnet member 14 when viewed from the side of a target. As shown in FIG. 10, the magnet member 14 usually has, e.g., a configuration in which an inner magnet 16 which has different polarity from that of an outer magnet 15 is disposed inside the outer magnet 15 having an annular shape. In this example, the polarity of the outer magnet 15 is adjusted such that the target side thereof becomes an S pole. The polarity of the inner magnet 16 is adjusted such that the target side thereof becomes an N pole. Thus, a horizontal magnetic field is formed near a lower surface of the target by virtue of a cusped magnetic field originating from the outer magnet 15 and a cusped magnetic field originating from the inner magnet 16. The horizontal magnetic field, which means a magnetic field having high horizontality, is a magnetic field showing a high degree of parallelism with respect to the lower surface of the target.

If an inert gas such as an argon (Ar) gas or the like is introduced into a vacuum chamber while applying a negative direct current voltage from a direct current power supply to the target, the Ar gas is ionized by an electric field. Consequently, Ar ions and electrons are generated. The Ar ions and electrons thus generated are drifted by the horizontal magnetic field and the electric field, and such drifting results in generating high-density plasma. The Ar ions existing in the plasma sputter the target such that metal particles are emitted from the target. A film is deposited on a substrate by the metal particles thus emitted.

Due to this mechanism, as shown in FIG. 11, an annular erosion 17 extending along the arrangement of the magnets is formed on the lower surface of the target just below the central region between the outer magnet 15 and the inner magnet 16. At this time, although the magnet member 14 is rotated in order to form the erosion 17 on the entire surface of the target 21, it is difficult to uniformly form the erosion 17 in the radial direction of the target 21 in such magnet arrangement mentioned above.

In the meantime, the film deposition speed distribution on the substrate plane depends on the intensity of the erosion of the target 21 (the magnitude of a sputter speed). Accordingly, when the degree of non-uniformity of the erosion 17 is large as set forth above, if the distance between the target 21 and the substrate S is set small as indicated by a dotted line in FIG. 11, the shape of the erosion is reflected as it is. Thus, the uniformity of the film deposition speed in the substrate plane becomes poor. For that reason, in the related art, a sputter process is performed by setting the distance between the target 21 and the substrate S to become a large value of from 50 mm to 100 mm.

At this time, the particles emitted from the target 21 by the sputtering are scattered outward. Therefore, if the substrate S is spaced apart from the target 21, the amount of the particles adhering to an adhesion-preventing shield is increased and the film deposition speed is reduced in the outer periphery portion of the substrate S. For that reason, it is typical that the uniformity of the film deposition speed in the substrate plane is secured by deepening the erosion in the outer periphery portion, namely by increasing the sputter speed in the outer periphery portion. In this configuration, however, the amount of the sputter particles adhering to the adhesion-preventing shield becomes larger. Therefore, the film deposition efficiency is as low as about 10% and a high film deposition speed cannot be obtained. As described above, in the conventional magnetron sputter device, both of the film deposition efficiency and the uniformity of the film deposition speed cannot be obtained together.

The target 21 needs to be replaced right before the erosion 17 reaches the rear surface of the target 21. As mentioned above, the erosion 17 is low in the in-plane uniformity. If there is a region where the erosion 17 grows fast, the replacement time of the target 21 is determined based on that region. For that reason, the use efficiency of the target 21 is reduced to about 40%. In order to assure cost-effectiveness and to enhance productivity, it is required to increase the use efficiency of the target 21.

In recent years, a tungsten (W) film draws attention as a wiring material of a memory device. It is required that the tungsten (W) film be deposited at a film deposition speed of, e.g., about 300 nm/min. In the aforementioned configuration, the film deposition speed can be secured by, e.g., setting the supplied power to become as large as about 15 kWh. However, as the mechanism is complex and the operation rate becomes low, it would eventually result in an increase of the manufacturing cost.

A related art discloses the following technology. A plurality of magnets each having a center axis parallel to a surface of a target is arranged such that the center axes thereof become substantially parallel to one another. The magnets are formed such that the N pole and the S pole thereof face each other in the direction substantially perpendicular to the center axes. The magnets are installed at the rear surface side of the target. Electrodes are formed in the upper and lower portions of a sputter device. A direct current voltage is applied to the upper electrode and high-frequency power is supplied to the upper electrode. According to the disclosure mentioned above, the point-cusped magnetic field formed by the magnet arrangement can be vertically moved through by using an electromechanical device. If a direct current voltage is applied to the magnetic field, the film deposition speed is made uniform. This makes it possible to realize a constant sputter speed.

Another related art discloses a technology characterized by a wafer holder in which a wafer is arranged on a surface of a rotating shaft. This technology can realize sputtering film deposition in such a way that the movement of the wafer holder is not hindered even if the distance between the target and the wafer is made short.

In the two related arts cited above, however, no attention is paid to a technology in which the distance between the target and the wafer is made short to enhance the film deposition efficiency while securing the in-plane uniformity of the film deposition speed. Even if the configurations of the two related arts are combined, it is not possible to solve the problems inherent in the prior art.

### SUMMARY

In view of the circumstances noted above, it is an object of the present disclosure to provide a sputter device capable of improving film deposition efficiency and target use efficiency while securing high in-plane uniformity in a film deposition speed on a substrate.

Provided is a sputter device in which a conductive target is disposed so as to face a workpiece substrate mounted on a mounting part located within a vacuum chamber, the sputter device configured to convert an inert gas introduced into the vacuum chamber to plasma and configured to sputter the target with ions existing in the plasma, the sputter device including a direct current power supply configured to apply a negative direct current voltage to the target, an opposing electrode installed at the opposite side of the workpiece substrate from the target so as to face the target, and a target high-frequency power supply connected to the target and configured to supply high-frequency power to the target in order to generate a high-frequency electric field between the opposing electrode and the target, wherein the distance between the target and the workpiece substrate during a sputtering process being 30 mm or less.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a vertical sectional view showing a sputter device according to a first embodiment of the present disclosure.

FIG. 2 is an explanatory view illustrating an operation of the first embodiment.

FIG. 3 is a graph representing the relationship of the film deposition efficiency and the in-plane distribution with respect to the distance between a target and a wafer in the prior art and the present disclosure.

FIG. 4 is a vertical sectional view showing a sputter device according to a second embodiment of the present disclosure.

FIG. 5 is a vertical sectional view showing a third embodiment of a sputter device according to the present disclosure.

FIG. 6 is a vertical sectional view showing a fourth embodiment of a sputter device according to the present disclosure.

FIG. 7 is a plan view showing a magnet member used in the fourth embodiment.

FIG. 8 is a graph representing the relationship between the current and the voltage plotted with respect to the kind and magnitude of the electric power supplied to a plasma space.

FIG. 9 is a graph representing a sputtering result in the sputter device according to the present disclosure.

FIG. 10 is a plan view showing the arrangement of magnets used in a conventional sputter device.

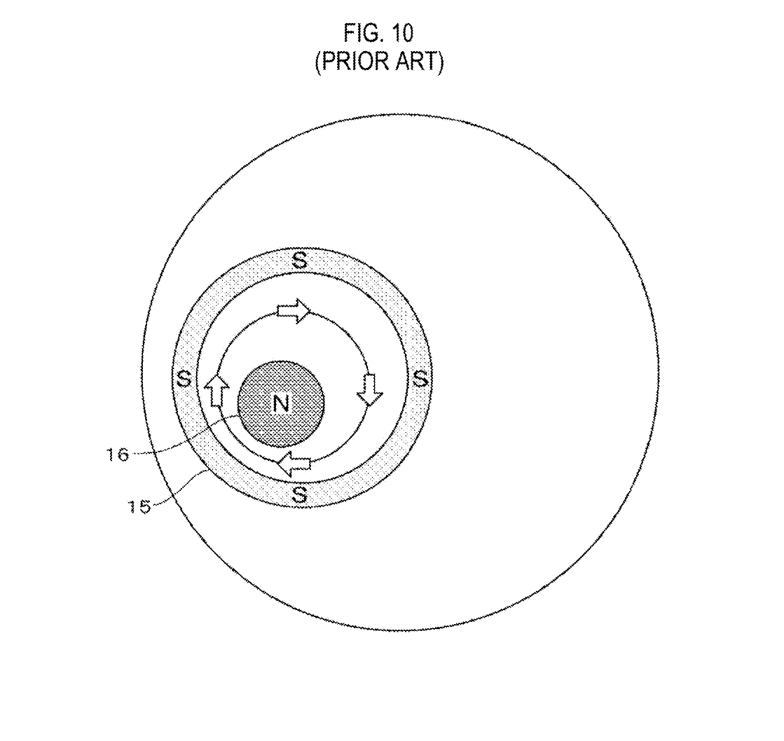

FIG. 11 is a vertical sectional view illustrating an operation of the conventional sputter device.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

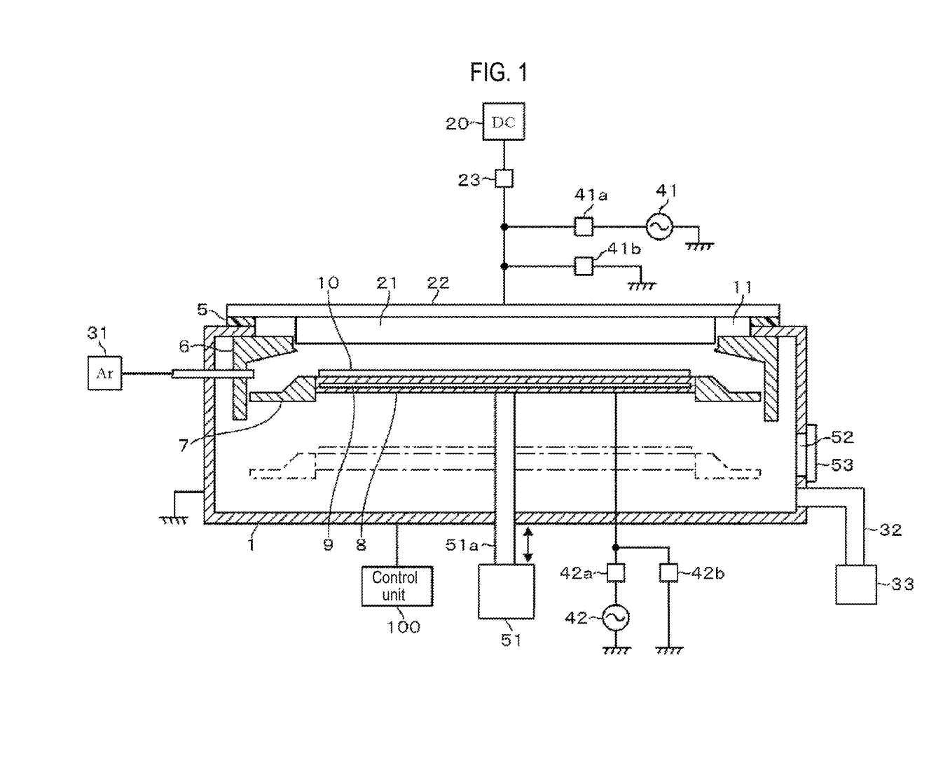

A sputter device according to a first embodiment of the present disclosure will now be described in detail with reference to the accompanying drawings. In FIG. 1, reference numeral 1 designates a grounded vacuum chamber 1 made of, e.g., aluminum (Al). The ceiling portion of the vacuum chamber 1 is opened. A conductive base plate 22 serving as a ceiling plate and made of, e.g., copper (Cu) or aluminum, is installed so as to close the opening 11. A target 21 made of a film deposition material, e.g., tungsten (W), titanium (Ti), aluminum, tantalum (Ta) or copper, and serving as an upper electrode is bonded to a lower surface of the base plate 22. The target 21 is formed into, e.g., a planar and circular shape. The diameter of the target 21 is set to become equal to, e.g., 400 to 450 mm, which is larger than the diameter of a semiconductor wafer (hereinafter referred to as “wafer”) 10 that constitute a substrate to be processed.

The base plate 22 is formed to become larger than the target 21 and is installed such that the peripheral edge region of the lower surface of the base plate 22 is mounted around the opening 11 of the vacuum chamber 1. At this time, an annular insulation member 5 is installed between the peripheral edge portion of the base plate 22 and the vacuum chamber 1. Thus, the target 21 is fixed to the vacuum chamber 1 in such a state that the target 21 is electrically insulated from the vacuum chamber 1. A direct current power supply 20 is connected to the base plate 22 through a filter unit 23. A negative direct current voltage is applied from the direct current power supply 20 to the base plate 22. Furthermore, a high-frequency power supply 41 (a target high-frequency power supply for supplying high-frequency power to the target) is connected to the base plate 22 through a filter unit 41a. The stop-band of the filter unit 23 covers the frequency of the high-frequency power supply 41 and the frequency of the lower high-frequency power supply 42 to be described later. Further, the base plate 22 is grounded through a filter unit 41b having a direct current cutoff function. The filter unit 41b has the stop-band covering the frequency of the high-frequency power supply 41, and the pass-band covering the frequency of the lower high-frequency power supply 42 to be described later.

Within the vacuum chamber 1, there is installed a mounting part 8 that horizontally mounts a wafer 10 so as to face the target 21 in a parallel relationship therewith. The mounting part 8 is configured to serve as an electrode (an opposing electrode) which is made of, e.g., aluminum. The high-frequency power supply 42 (an opposing electrode high-frequency power supply for supplying high-frequency power to the opposing electrode) is connected to the mounting part 8 through a filter unit 42a whose stop-band covers the frequency of the high-frequency power supply 41. Moreover, the mounting part 8 is grounded through a filter unit 42b whose pass-band covers the frequency of the high-frequency power supply 41 and whose stop-band covers the frequency of the high-frequency power supply 42.

The mounting part 8 is configured to move up and down by an elevator mechanism 51 between a transfer position in which the wafer 10 is carried into and out of the vacuum chamber 1 and a processing position in which sputtering is performed. In the processing position, the distance between the upper surface of the wafer 10 mounted on the mounting part 8 and the lower surface of the target 21 is set equal to, e.g., 10 mm or more and 30 mm or less. Reference numeral 51a designates an elevator shaft. While not shown in the drawings, the elevator shaft 51a is configured to move up and down while maintaining air-tightness with respect to the bottom portion of the vacuum chamber 1 through the use of a bearing unit and a bellows. The mounting part 8 is insulated from the vacuum chamber 1.

A heater 9 that constitutes a heating mechanism is arranged within the mounting part 8 so that the wafer 10 can be heated to, e.g., 400 degree C. Protruding pins (not shown) that pass through the mounting part 8 to deliver the wafer 10 between the mounting part 8 and the external transfer arm (not shown) are installed below the mounting part 8.

Within the vacuum chamber 1, an annular adhesion-preventing shield member 6 is installed so as to surround the lower side of the target 21 along the circumferential direction, and an annular holder shield member 7 is installed so as to surround the lateral side of the mounting part 8 along the circumferential direction. The adhesion-preventing shield member 6 and the holder shield member 7 are installed to prevent sputter particles from adhering to the inner wall of the vacuum chamber 1 and are made of a conductive material such as, e.g., aluminum or aluminum-based alloy. The adhesion-preventing shield member 6 is connected to, e.g., the inner wall of the ceiling portion of the vacuum chamber 1 and is grounded through the vacuum chamber 1.

The vacuum chamber 1 is connected to a vacuum pump 33 as a vacuum exhaust mechanism through an exhaust path 32 and is also connected to a supply source of an inert gas, e.g., an Ar gas, through a supply path. In the drawings, reference numeral 52 designates a transfer gate for the wafer 10, which can be opened and closed by a gate valve 53.

The sputter device having the configurations described above includes a control unit 100 that controls an operation of supplying electric power from the direct current power supply 20 or the high-frequency power supplies 41 and 42, an operation of supplying an Ar gas, an operation of moving the mounting part 8 up and down with the elevator mechanism 51, an operation of exhausting the vacuum chamber 1 with the vacuum pump 33 and a heating operation using the heater 9. The control unit 100 includes, e.g., a computer that includes a CPU and a storage section not shown. A program including a step (command) group regarding the control required for the magnetron sputter device to perform film deposition on the wafer 10 is stored in the storage section. The program is stored in a storage medium such as, e.g., a hard disc, a compact disc, a magneto-optical disc, a memory card or the like and is installed from the storage medium into the computer.

Next, description will be made on an operation of the sputter device described above. First, the transfer gate 52 of the vacuum chamber 1 is opened and the mounting part 8 is disposed in a delivery position. The wafer 10 is delivered to the mounting part 8 by the cooperative work of the external transfer mechanism and the pushup pins (not shown). Subsequently, the transfer gate 52 is closed and the mounting part 8 is moved up to the processing position. An Ar gas is introduced into the vacuum chamber 1. The vacuum chamber 1 is exhausted by the vacuum pump 33 to keep the interior of the vacuum chamber 1 at a predetermined vacuum level, e.g., 1.33 Pa to 13.3 Pa (10 mTorr to 100 mTorr). In the meantime, a negative voltage is applied to the target 21 such that the direct current power of, e.g., 100 W to 2 kW, is supplied from the direct current power supply 20 to a plasma generation space. The high-frequency power of about 100 W to 500 W is supplied from the high-frequency power supply 41 to the target 21, and the high-frequency power of about 100 W to 500 W is supplied from the high-frequency power supply 42 to the mounting part 8. The respective frequencies of the high-frequency power supplies 41 and 42 are selected from, e.g., 100 kHz to 100 MHz and are set at different values.

As a result, an electric field is generated between the target 21 and the mounting part 8. The Ar gas is partially ionized and divided into Ar ions and electrons. Thus, the Ar gas is converted to a plasma state. That is to say, the speed, at which the Ar gas is divided into Ar ions and electrons by the electric field, and the speed, at which the Ar ions are recombined with the electrons to become the Ar gas again, are kept in an equilibrium state. Thus, the plasma state is maintained. Since the negative direct current voltage is being applied to the target 21, the Ar ions are attracted toward, and collided with, the target 21. The Ar ions thus collided sputter the target 21, whereby particles are emitted from the target 21 and are scattered into the vacuum chamber 1.

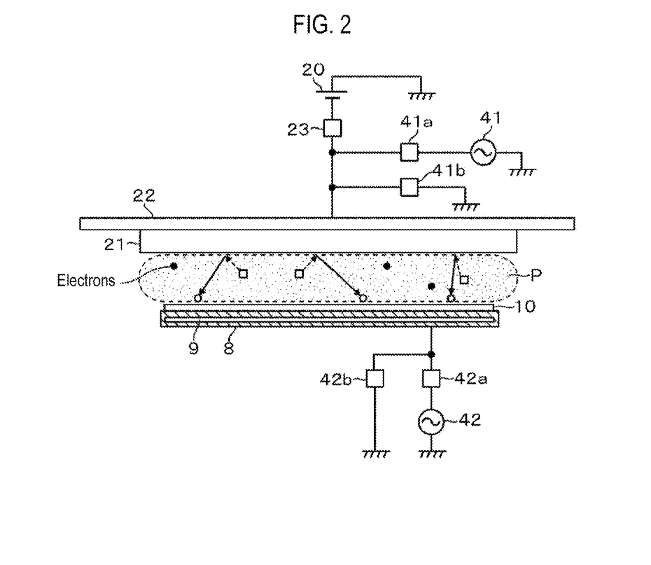

The particles adhere to the surface of the wafer 10 mounted on the mounting part 8. Consequently, a thin film formed from a film deposition material that constitutes the target 21, e.g., tungsten, is formed on the wafer 10. The high-frequency power supplied to the mounting part 8 contributes to the conversion of the Ar gas to the plasma and serves to apply a bias voltage to the mounting part 8. For that reason, due to the synergistic action with the heating operation performed by the heater 9, the thin film has a low resistance and becomes dense. The particles that deflect from the wafer 10 adhere to the adhesion-preventing shield member 6 or the holder shield member 7. Such a series of operations are schematically illustrated in FIG. 2. In FIG. 2, symbol o indicates tungsten particles, symbol □ indicates argon ions, black circles indicate electrons, and symbol P indicates plasma.

The plasma is generated by the direct current voltage and the high-frequency power which are supplied to between the target 21 and the mounting part 8. Thus, the plasma density is highly uniform in the plane direction of the target 21. For that reason, the in-plane uniformity of erosion in the target 21 becomes higher. Therefore, even if the distance (spaced-apart distance) TS between the target 21 and the wafer 10 is made short to some extent, the film deposition speed on the surface of the wafer 10 is hard to become non-uniform. Accordingly, the distance between the target 21 and the wafer 10 can be made short to fall within a range of, e.g., from 10 mm to 30 mm. At this time, if the wafer 10 is moved away from the target 21, the film deposition speed decreases in the outer periphery portion of the wafer 10. This is because the particles sputtered at the outer periphery side of the target 21 will be scattered toward the outside of the wafer 10, consequently reducing the film deposition efficiency. On the contrary, if the target 21 and the wafer 10 are excessively moved toward each other, the plasma generation space becomes narrow and the plasma discharge may be difficult to occur. In view of this, it is preferred that the distance between the target 21 and the wafer 10 is set equal to or larger than 10 mm.

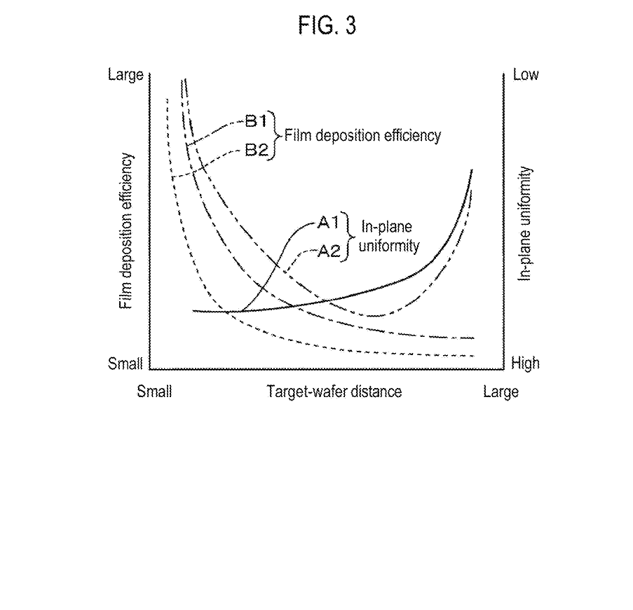

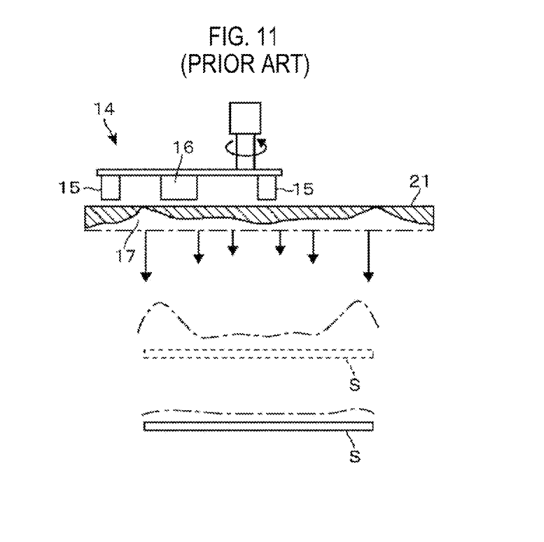

Since the wafer 10 is disposed just below the target 21, the particles sputtered from the target 21 rapidly adhere to the wafer 10. For that reason, the amount of the sputtered particles that contribute to the formation of the thin film on the wafer 10 becomes larger and the film deposition efficiency grows higher. In this regard, the film deposition efficiency refers to the ratio of the sputtered particles adhering to the wafer 10 to form the thin film to the sputtered particles emitted from the target 21. FIG. 3 is a characteristic diagram representing the relationship of the film deposition efficiency and the in-plane uniformity of the film deposition speed with the distance between the target 21 and the wafer 10. The horizontal axis indicates the distance, the left vertical axis indicates the film deposition efficiency, and the right vertical axis indicates the in-plane uniformity of the film deposition speed. As for the in-plane uniformity of the film deposition speed, solid line A1 corresponds to the configuration of the present disclosure, and double-dotted chain line A2 corresponds to the configuration of the prior art (the configuration shown in FIG. 11). With regard to the film deposition efficiency, single-dotted chain line B1 corresponds to the configuration of the present disclosure, and dotted line B2 corresponds to the data of the prior art configuration.

As can be noted from FIG. 3, in the configuration of the present disclosure, the in-plane uniformity of the film deposition speed and the film deposition efficiency become better as the distance grows smaller. It is therefore possible to make compatible the in-plane uniformity of the film deposition speed and the film deposition efficiency. In addition, by increasing the size of the target, it is possible to secure good in-plane uniformity and to improve the use efficiency of the target. These effects become conspicuous as the internal atmosphere of the device is maintained at a lower pressure.

In contrast, in the prior art configuration, if the distance between the target 21 and the wafer 10 is small, the in-plane uniformity of the film deposition speed becomes very low. The in-plane uniformity of the film deposition speed grows higher as the distance increases. If the distance becomes larger than a certain dimension, the in-plane uniformity of the film deposition speed decreases again. For that reason, the distance between the target 21 and the wafer 10 should be increased in order to secure high in-plane uniformity. However, if the distance is made larger, the film deposition efficiency becomes significantly lower than that available in the configuration of the present disclosure.

According to the aforementioned embodiment, the direct current power is supplied to between the target and the opposing electrode by applying the negative direct current voltage to the target. Furthermore, a high-frequency electric field is formed between the target and the opposing electrode by overlapping the high-frequency power with the target. For that reason, high-density plasma having high uniformity in the plane of the target is generated. Accordingly, erosion having high uniformity in the plane of the target is generated. Thus, in the case when the substrate is disposed near a position spaced apart 30 mm or less from the target, it is possible to obtain high in-plane uniformity in the film deposition speed. As a result, the amount of the sputtered particles that come off from the wafer 10 and adhere to the adhesion-preventing shield member 6 or the holder shield member 7 is reduced. It is therefore possible to both obtain high film deposition efficiency and high in-plane uniformity in the film deposition together. By setting the distance at 30 mm or less, it can be expected that the film deposition speed becomes more than twice as high as the film deposition speed available in the prior art shown in FIG. 11.

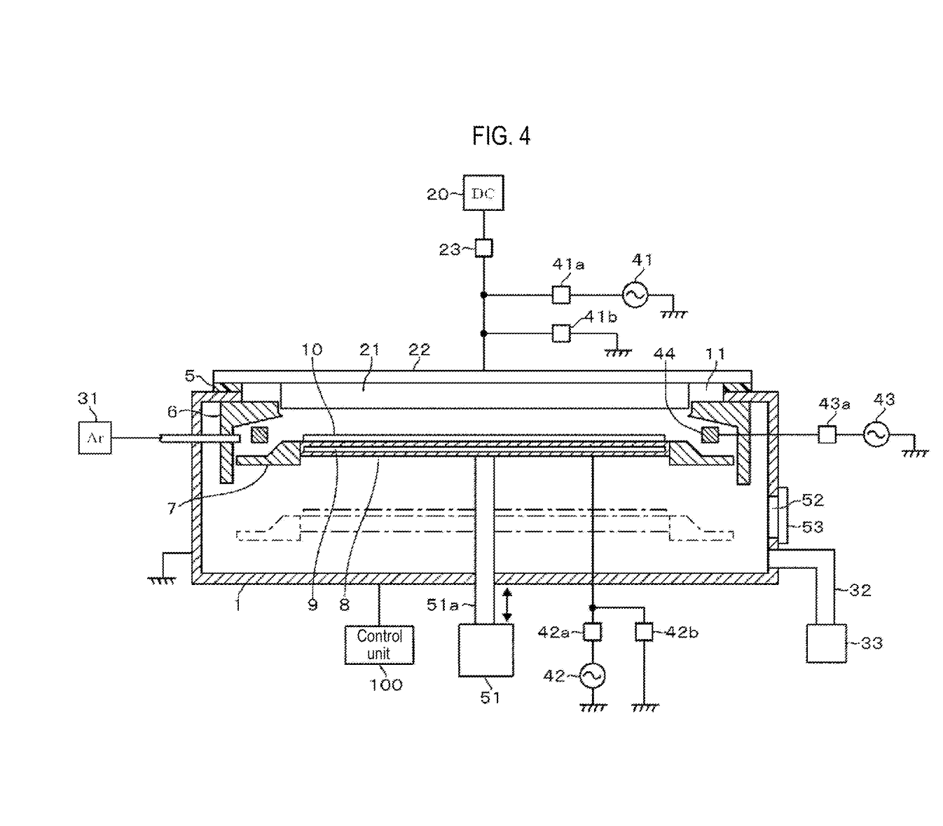

In a second embodiment of the present disclosure, as shown in FIG. 4, it may be possible to install, in addition to the configurations of the first embodiment, a ring-shaped auxiliary electrode 44 and a high-frequency power supply 43 (an auxiliary high-frequency power supply for supplying high-frequency power to the auxiliary electrode) connected to the auxiliary electrode 44. The auxiliary electrode 44 is formed into a ring-like shape such that the auxiliary electrode 44 surrounds a space existing between the mounting part 8 and the target 21 in a more outward position than the wafer 10. If there is a possibility that a bias voltage is directly generated in the auxiliary electrode 44, as a result of which the auxiliary electrode 44 is sputtered, it is preferred that the auxiliary electrode 44 is made of the same material as the target 21.

The frequency of the high-frequency power supply 43 is selected from a range, e.g., from 100 kHz to 100 MHz, and is set at a value differing from the frequencies of the high-frequency power supplies 41 and 42. The electric power of the high-frequency power supply 43 is set to fall within a range of, e.g., from 100 W to 1000 W. A filter 43a whose stop-band covers the frequencies of the high-frequency power supplies 41 and 42 and whose pass-band covers the frequency of the high-frequency power supply 43, is installed in a conductive path between the high-frequency power supply 43 and the auxiliary electrode 44. In order to generate electric discharge between the auxiliary electrode 44, the target 21 and the mounting part 8, the filter units 41b and 42b may be designed such that the pass-band thereof covers the high frequency of the high-frequency power supply 43. In order to generate electric discharge between the auxiliary electrode 44 and one of the target 21 and the mounting part 8, the pass-band of one of the filter units 41b and 42b may be adjusted such that the pass-band thereof covers the high frequency of the high-frequency power supply 43.

By installing the auxiliary electrode 44 so as to surround the space that exists below the target 21 and supplying the high-frequency power to the space through the auxiliary electrode 44 in the aforementioned manner, it is possible to increase the density of plasma and to adjust the plasma density at the lower side of the peripheral edge portion of the target 21. Therefore, as compared with the case of the first embodiment, it is possible to increase the uniformity of an erosion distribution. In the embodiment that employs the auxiliary electrode 44, the mounting part 8 is not limited to the configuration in which the high-frequency power supply 42 is connected to the mounting part 8.

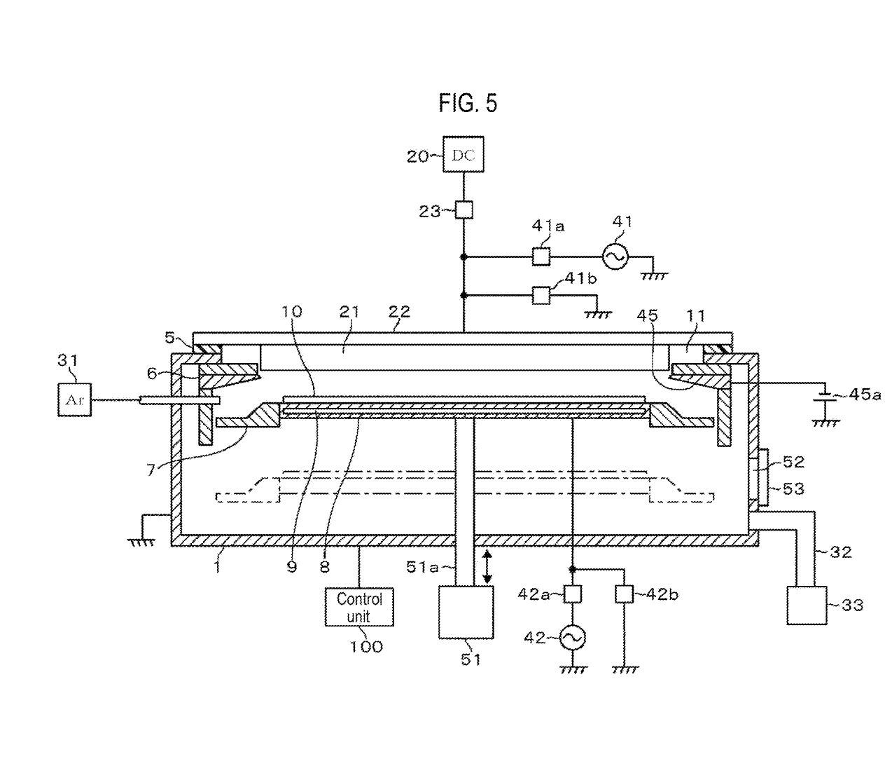

In a third embodiment of the present disclosure, as shown in FIG. 5, it may be possible to install, in addition to the configurations of the first embodiment, a ring-shaped conductive electron reflecting member 45 that surrounds a region near the lower surface of the target 21, i.e., a space below the target 21. When seen in a sectional view, the conductive electron reflecting member 45 extends outward from the peripheral edge portion of the target 21. Thus, the conductive electron reflecting member 45 serves as an adhesion-preventing shield. More specifically, the height-direction central portion of the adhesion-preventing shield member 6 used in the first embodiment is replaced by the electron reflecting member 45. An insulating body (not shown) is interposed between the portion existing above the electron reflecting member 45, which corresponds to the adhesion-preventing shield member 6, and the electron reflecting member 45. Accordingly, the electron reflecting member 45 is electrically insulated from the adhesion-preventing shield member 6 (the ground) and is kept at a negative electric potential of several to several tens V by a direct current power supply 45a. In this case, the electrons existing in the plasma is reflected by the electron reflecting member 45 and is returned toward the center of the target 21. Thus, the plasma density increases in the position just below the target 21. This makes it possible to increase the current density in the target 21. Even in this example, it is possible to adjust the plasma density at the lower side of the peripheral edge portion of the target 21 and to obtain high in-plane uniformity in the erosion distribution and the film deposition distribution.

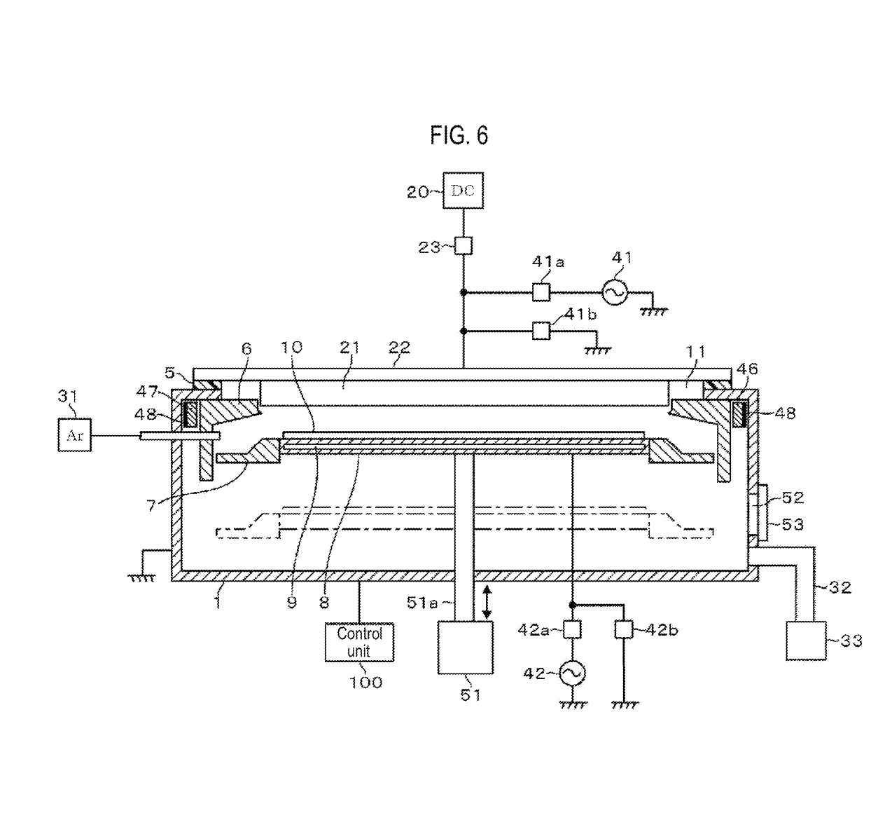

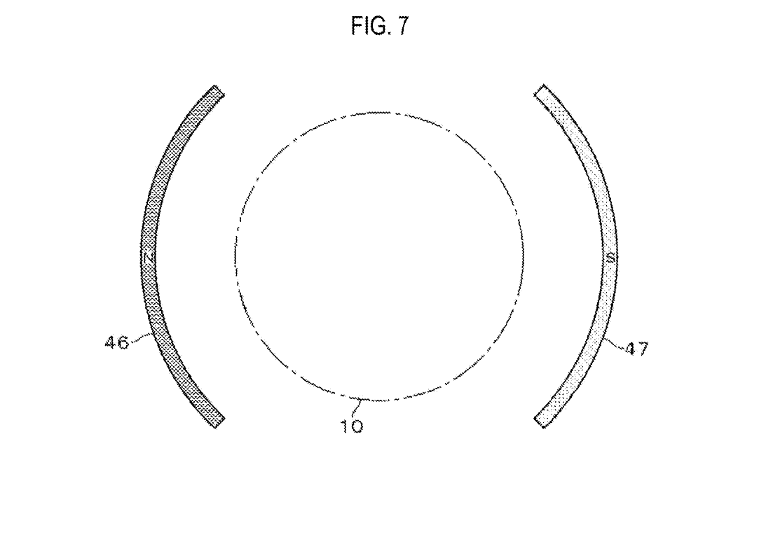

In a fourth embodiment of the present disclosure, as shown in FIGS. 6 and 7, it may be possible to install, in addition to the configurations of the first embodiment, magnets at the rear surface side of the adhesion-preventing shield member 6. An N-pole magnet 46 and an S-pole magnet 47 are used as the magnets. The magnets 46 and 47 are disposed to face each other with the center axis of the target 21 interposed therebetween. Thus, during the sputtering operation, a cusped magnetic field is formed near the intermediate region between the target 21 and the mounting part 8. The cusped magnetic field reflects electrons in a mirror-like manner and confines plasma to a region just below the target 21, thereby playing a role of increasing the plasma density. Thus, the plasma density can be made higher than that of the first embodiment by adjusting the high-frequency power of the high-frequency power supplies 41 and 42 and the process conditions. Since the plasma density can be adjusted in the radial direction of the target 21, it is possible to improve the erosion distribution, the film deposition efficiency and the in-plane uniformity of the film deposition speed.

At least two of the second embodiment, the third embodiment and the fourth embodiment may be combined with the first embodiment. When combining these embodiments, the high-frequency power supply 42 of the mounting part 8 may not be used.

The film forming device of the present disclosure described above can be applied to not only the process of sputtering the semiconductor wafer but also a process of sputtering other workpiece substrates such as a liquid crystal display, a glass sheet for a solar cell and the like.

### EXAMPLES

Next, two examples and two reference examples on the sputter device according to the present disclosure will be described.

### Example 1

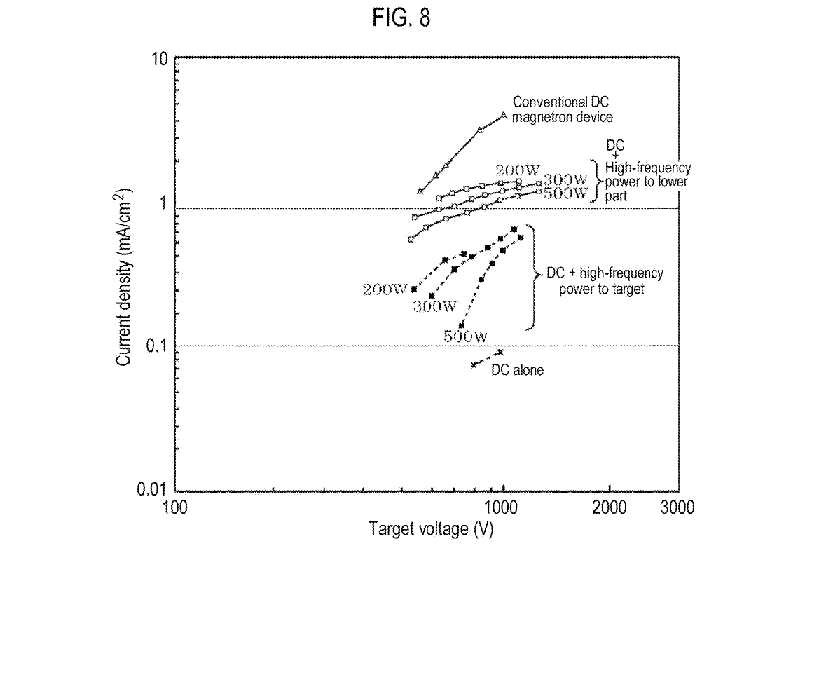

Using the device shown in FIG. 1, a direct current voltage was applied from the direct current power supply 20 to the target 21 and high-frequency power of 13.56 MHz was supplied from the high-frequency power supply 41 to the target 21. The density of a current flowing through the target 21 was investigated. In this case, no high-frequency power was supplied from the high-frequency power supply 42. The diameter of the wafer 10 is 300 mm. The material of the target 21 is tungsten. The diameter of the target 21 is 450 mm. The distance between the target 21 and the wafer 10 is 20 mm. The pressure of the processing atmosphere is 1.33 Pa (10 mTorr). The high-frequency power of the high-frequency power supply 41 was set at three different values, 200 W, 300 W and 500 W. The direct current voltage was changed with respect to the respective values of the high-frequency power. The plots interconnected by dotted lines in FIG. 8 show the results.

### Reference Example 1-1

Using the device shown in FIG. 1, the direct current voltage supplied from the direct current power supply 20 was changed without supplying high-frequency power from the high-frequency power supplies 41 and 42. The density of a current flowing through the target 21 was investigated. Other conditions are identical with those of Example 1. The plots of a chain line in the lowermost region in FIG. 8 show the result.

### Reference Example 1-2

Using the device shown in FIG. 1, high-frequency power of 13.56 MHz was supplied from the high-frequency power supply 42 to the mounting part 8 without supplying high-frequency power from the high-frequency power supply 41. The density of a current flowing through the target 21 was investigated. The high-frequency power of the high-frequency power supply 42 was set at three different values, 200 W, 300 W and 500 W. The direct current voltage was changed with respect to the respective values of the high-frequency power. The plots interconnected by solid lines in FIG. 8 show the results.

As can be noted from the aforementioned results, when only the direct current discharge is generated, the density of a current flowing through the target 21 is 0.1 mA/cm² or less and the film deposition speed is several nm/min or less. If the high-frequency power supplied from the high-frequency power supply 41 is overlapped with the direct current voltage, the current density is increased up to a range of from 0.2 mA/cm² to 0.8 mA/cm² and the film deposition speed is increased up to about 50 nm/min. The reason for the current density becoming larger in this way is that the supply of the high-frequency power leads to an increase in the ionization efficiency of an Ar gas, an increase in the plasma density, an increase in the number of Ar ions and an increase in the sputtering speed. The in-plane uniformity of the thickness of a tungsten film formed on the wafer 10 is so good as to fall within 5%.

If the high-frequency power is supplied to the target 21, an electric potential is generated in the target 21 and is applied to the direct current power supply 20 as a direct current voltage. This electric potential grows higher as the high-frequency power becomes larger. Thus, if the high-frequency power is made larger, there is a need to increase the direct current voltage of the direct current power supply 20. For that reason, due to the restriction-on-use of the direct current power supply 20 used in the test, the density of a current flowing through the target 21 could not be increased to 1 mA/cm² or more. However, the current density can be increased by using a proper direct current power supply 20.

Even when the high-frequency power is supplied to the mounting part 8, the current flowing through the target 21 is increased. As illustrated in FIG. 8, the current density available in this case can be set as high as 1.2 mA/cm² by adjusting the direct current voltage and the value of the high-frequency power. Moreover, a value of about 50 nm/min is obtained as the film deposition speed. Even if the high-frequency power is supplied to the mounting part 8, there is no possibility that the electric potential of the target 21 is increased as mentioned above. However, if the high-frequency power supplied to the mounting part 8 is increased, a negative electric potential is generated in the wafer 10 and Ar ions are drawn into the wafer 10. Thus, the etching amount of the film formed on the wafer 10 is increased and a high film deposition speed is not sufficiently obtained. For that reason, it is not desirable to excessively increase the high-frequency power.

Even when the high-frequency power is supplied to the target 21, just like the case where the high-frequency power is supplied to the mounting part 8, the current density can be increased by selecting to use the direct current power supply 20. For that reason, it is preferred that the plasma density is increased by supplying the high-frequency power having such an intensity as not to manifest the influence of etching to the mounting part 8 while supplying the high-frequency power to the target 21.

### Example 2

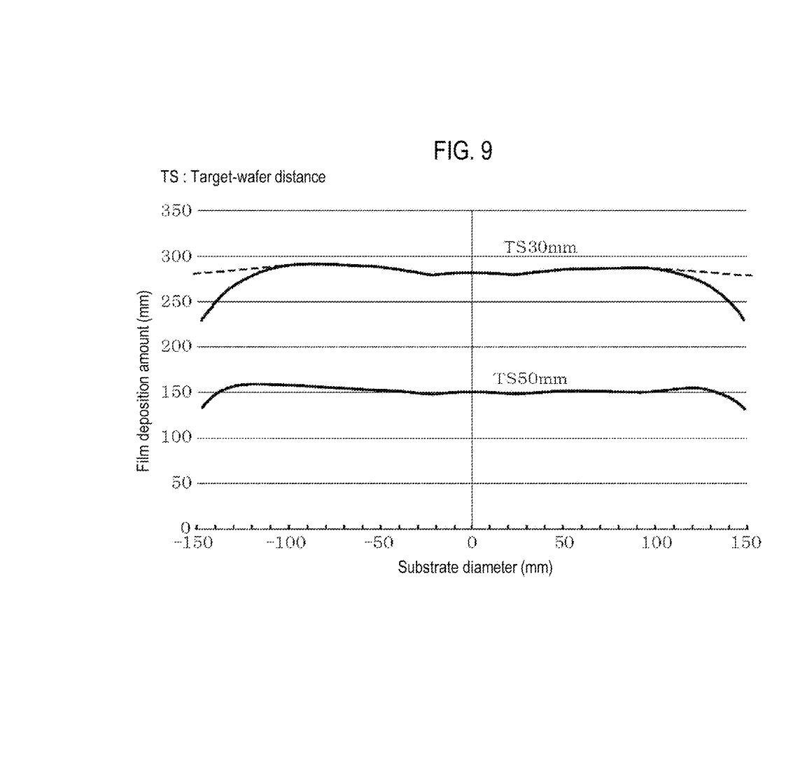

Using the device shown in FIG. 1, direct current power of 200 W was supplied from the direct current power supply 20 to the target 21 and high-frequency power of 13.56 MHz and 200 W was supplied from the high-frequency power supply 41 to the target 21. In this state, sputtering was performed for a case where the distance TS between the target 21 and the wafer 10 is 30 mm and a case where the distance TS between the target 21 and the wafer 10 is 50 mm. The diameter of the wafer 10 is 300 mm. The material of the target 21 is tungsten. The diameter of the target 21 is 330 mm. The pressure is 1.33 Pa (10 mTorr). The processing time is 60 seconds. A film deposition amount was measured over the entire surface and a film thickness distribution was investigated in three regions existing along the diameter of the wafer. That is to say, the region (linear region) between the intersection points of a line extending along the diameter of the wafer and circles concentric with the center of the wafer is divided at an equal interval. The film thickness at the equally dividing points is measured. Based on the film thickness thus measured, a film thickness distribution is found in the below-mentioned manner. FIG. 9 is a view representing the relationship between the tungsten film thickness measured from one end side to the other end side of the diameter along the diameter of the wafer and the positions on the wafer (the positions in the radial direction with the center position indicated by “0”).

With respect to the circle diameters of 300 mm, 280 mm and 250 mm, the film thickness was measured in the aforementioned manner and the film thickness distribution was found for every diameter. In the following description, the film thickness distribution on a line extending along the diameter of a circle having a diameter of 300 mm will be abbreviated as “Φ 300 mm film thickness distribution”. This holds true for the diameters Φ 280 mm and Φ 250 mm. In case of the diameters Φ 300 mm, Φ 280 mm and Φ 250 mm, the numbers of the equally dividing points are 41, 38 and 35, respectively. The calculation formula of the film thickness distribution is as follows.

Film thickness distribution (%)={standard deviation (1σ)/average value of film thickness in individual points}×100

The Φ 300 mm film thickness distribution was 4.7% if TS=30 mm and 3.0% if TS=50 mm. The Φ 280 mm film thickness distribution was 3.7% if TS=30 mm and 2.4% if TS=50 mm. The Φ 250 mm film thickness distribution was 1.9% if TS=30 mm and 2.1% if TS=50 mm.

Referring first to FIG. 9, it can be noted that, if the TS is 30 mm, the film deposition speed becomes about twice as high as the film deposition speed obtained when the TS is 50 mm. In case where the TS is 30 mm, the Φ 300 mm film thickness distribution is 4.7% and the Φ 250 mm film thickness distribution is so good as to be less than 2%. The reason for the Φ 300 mm film thickness distribution being inferior to the Φ 250 mm film thickness distribution is that, since the diameter of the target has a finite value of 330 mm, the amount of flying particles becomes smaller in the outer periphery region than in the central region, as a result of which the film deposition speed decreases in the outer periphery region. In this example, the target diameter is 330 mm. However, if the target diameter is 400 mm, it is possible to expect a result that the Φ 300 mm film thickness distribution becomes less than 2%. Since there is a need to increase the TS, it is often the case that the diameter of the target used in depositing a film on a 300 mm wafer 10 is about 450 mm.

However, when TS=30 mm, the film thickness distribution is a little inferior to the film thickness distribution available when TS=50 mm. If the density distribution on the target surface is assumed to be uniform and if TS is increased, i.e, when TS=50 mm, the film deposition speed in the outer periphery portion would be reduced more sharply. However, this does not hold true in reality. Presumably, the reason would be that, due to the increase in the TS, the distribution of RF discharge is changed and the discharge space is widened, as a result of which the plasma is spread to the outer periphery portion of the target. In case where TS=50 mm, it is hard to say that the film thickness distribution accurately reflects the target erosion distribution.

Making further speculation in this regard, when based on the film deposition efficiency obtained when the TS is 30 mm and the target diameter is 330 mm, the film deposition efficiency obtained when the TS is 50 mm and the target diameter 330 mm was about 53%. Thus, the target use efficiency becomes 53% just like the film deposition efficiency. If the plasma density is made uniform and if the TS is set equal to 30 mm with the target diameter equal to 400 mm, the calculated target use efficiency becomes 68% which is 15% higher than the target use efficiency 53% obtained when the TS is 50 mm. This means that the effect of reducing the TS is remarkable.

In order to increase the film deposition speed and to improve the film thickness distribution in the peripheral edge portion of the wafer while keeping the TS equal to 30 mm with the target diameter equal to 330 mm, it is preferred that a lower pressure condition is formed to assure easier spreading of the plasma. It can be said that it is desirable to perform the process at 1.33 Pa (10 mTorr) or less which is the condition of this example. The electric power capable of starting electric discharge at a low pressure is from 100 to 200 W in terms of RF and is a range permitted by the impedance of the power supply in terms of DC. It surely depends on the power supply device. If the range of plasma is widened by reducing the pressure, it is possible to improve the in-plane uniformity of the film thickness. Similarly, the in-plane uniformity of the film thickness can be improved by using an auxiliary electrode. This is because, by supplying electric power through the auxiliary electrode, it becomes possible to increase the density of plasma and to adjust the density distribution.

According to the present disclosure, a direct current voltage is applied to between the target and the opposing electrode by applying a negative direct current voltage to the target. A high-frequency electric filed is formed between the target and the opposing electrode by overlapping high-frequency power with the target. Thus, high-density plasma having high uniformity in the plane of the target is generated. Accordingly, there is generated an erosion having high uniformity in the plane of the target. Therefore, even if the substrate and the target are positioned close to each other at a distance of 30 mm or less, it is possible to obtain high in-plane uniformity in the film deposition speed on the substrate. As a result, it is possible to obtain high in-plane uniformity in the film deposition while obtaining high film deposition efficiency (the ratio of the sputtered particles adhering to the substrate to the amount of the particles emitted from the target).

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A sputter device in which a conductive target having a planar and circular shape is disposed so as to face a workpiece substrate mounted on a mounting part located within a vacuum chamber, the sputter device configured to convert an inert gas introduced into the vacuum chamber to plasma and configured to sputter the target with ions existing in the plasma, the sputter device comprising:
a direct current power supply configured to apply a negative direct current voltage to the target;
an opposing electrode installed at the opposite side of the workpiece substrate from the target so as to face the target; and
a target high-frequency power supply connected to the target and configured to supply high-frequency power to the target in order to generate a high-frequency electric field between the opposing electrode and the target,
wherein the distance between the target and the workpiece substrate during a sputtering process being 30 mm or less.

2. The device of claim 1, further comprising:
an opposing-electrode high-frequency power supply connected to the opposing electrode, and configured to supply high-frequency power to the opposing electrode in order to generate a high-frequency electric field between the target and the opposing-electrode.

3. The device of claim 1, further comprising:
a heating unit configured to heat the workpiece substrate mounted on the mounting part.

4. The device of claim 1, further comprising:
an auxiliary electrode installed so as to surround a region extending from a lower surface of the target to the workpiece substrate in a position more outward than an outer periphery of the workpiece substrate when viewed from the above; and
an auxiliary power supply configured to perform an operation of supplying high-frequency power with respect to the auxiliary electrode.

5. The device of claim 1, further comprising:
an electron reflecting member extending outward from a peripheral edge portion of the target in a space existing below the target; and
a direct current power supply configured to maintain the electron reflecting member at a negative electric potential.

6. The device of claim 1, further comprising:
an annular adhesion-preventing shield member installed to surround a lower side of the target and configured to prevent sputtered particles from adhering to an inner wall of the vacuum chamber; and
a magnet disposed between the adhesion-preventing shield member and the inner wall of the vacuum chamber,
the magnet including an N-pole magnet and an S-pole magnet which are disposed to face each other with a center axis of the target interposed therebetween.
